(19) United States
(12) Patent Application Publication
(10) Pub. No.: US 2002/0048851 A1
(43) Pub. Date: Apr. 25, 2002

(54) Process for making a semiconductor package

(76) Inventors: Chikao Ikenaga, Tokyo (JP); Kouji Tomita, Tokyo (JP)

Correspondence Address: FLYNN, THIEL, BOUTELL & TANIS, P.C., 2026 Rambling Road, Kalamazoo, MI, 49008-1699, US

(21) Appl. No.: 09/905,857

(22) Filed: Jul. 13, 2001

(30) Foreign Application Priority Data
Jul. 14, 2000 (JP) 2000-213721

(51) Int. Cl. H01L 21/48; H01L 21/44; H01L 21/50

(52) U.S. Cl. 438/113

(57) ABSTRACT

Semiconductor devices are mounted on die-pads supported with suspending leads of lead frames, and wire-bonding of electrodes provided on the top face of semiconductor devices to terminals of lead frames is made. Then, semiconductor devices are individually molded. Thereafter, individually molded semiconductor devices are stamped out to form individual semiconductor packages. In the above-mentioned process for making a semiconductor packages, resin tapes are stuck on the backside of terminals prior to the molding process, and the resin tapes are removed after the molding process. Since resin passes around behind terminals during the molding process, the occurrence of thin burrs on the backside of terminals are not found. Further, the satisfactory soldering plating in the mounting process of semiconductor packages can be secured without the process for removing burrs from the backside of terminals in which the process for removing burrs has been carried out conventionally.

### BACKGROUND OF THE INVENTION

1. Field of the Invention

The present invention relates to a process for making a semiconductor package comprising the steps of mounting semiconductor devices on lead frames, respectively, and encapsulating the outside thereof, particularly the upper side of the semiconductor devices.

2. Description of the Prior Art

In recent years, it has been required to miniaturize and make thinner semiconductor product mounted on a substrate, as mounting semiconductor on a substrate is made denser. It has been severely required for LSI to reduce the number of chips by improving integration level and to miniaturize and make lighter a package. The popularization of so-called CSP (Chip Size Package) is rapidly advancing. Particularly, in the development of thin semiconductor product with lead frame, the semiconductor package of single side encapsulated type has been developed in which a semiconductor device is mounted on a lead frame and the surface of semiconductor device mounted on a lead frame is encapsulated with molding compound.

FIG. 1 is a sectional view of one example of semiconductor package. FIG. 2 is a plan view thereof. The semiconductor package shown in FIGS. 1 and 2 is comprised of a lead frame 1, a semiconductor device 4 mounted on die-pad 3 supported with suspending leads 2 of lead frame 1, metallic thin wires 6 electrically connecting electrodes provided on the top face of the semiconductor device 4 with terminals 5 of lead frame 1, respectively and molding compound 7 for encapsulating the outside region of semiconductor device 4 including the upper side of semiconductor device 4 and the lower side of die-pad 3. The semiconductor package is of non-lead type in which so-called outer leads are not projected from the semiconductor package and the two of inner leads and outer leads are integrated into terminals 5, wherein the lead flame 1 used as semiconductor is half-cut by etching in such a manner that die-pad 3 is positioned higher than terminals 5. Since such a step is formed between die pads 3 and terminals 5, molding compound 7 can be inserted into the lower side of die-pad 3 so that a thin semiconductor package can be realized even though the semiconductor package has non-exposed die-pad.

Since semiconductor device is miniature, a matrix type frame is mainly used for the above-mentioned semiconductor package of non-lead type, in which plural semiconductor devices are arranged in a direction of a width of the matrix type frame. Further, recently, from a demand for cost down, it is thought to switch over a frame of individually molding type shown in FIG. 3 to a frame of individually molding type shown in FIG. 4.

In the frame of individually molding type, as shown in FIG. 3(A), individual molding cavities C of small size are provided separately within a frame F. After molding, individual semiconductor packages are stamped out so that semiconductor packages S shown in FIG. 3(B) are obtained. Namely, semiconductor devices are mounted on die-pads of lead frames through silver paste and others, and wire bonding is carried out. Thereafter, respective semiconductor devices are individually molded with molding compound and the respective molded semiconductor devices are stamped out to form individual semiconductor packages.

In the frame of individually molding type, as shown in FIG. 4(A), some molding cavities C of large size are provided within a frame F. Multiple semiconductor devices are arranged in matrix within each molding cavity C, respectively and individually molded with molding compound. Thereafter, the individually molded semiconductor devices are cut at grid-leads L by means of dicing saw so that a semiconductor package S shown in FIG. 4(B) is obtained. Namely, semiconductor devices are mounted on die-pads of lead frames through silver pastes and others and wire bonding is carried out. Thereafter, plural semiconductor devices arranged are individually molded with molding compound to a given cavity size, and then the individually molded semiconductor devices are cut to form individual semiconductor packages by dicing.

In the above-mentioned process of making a semiconductor package, after molding of resin, resin passes around behind terminals so that thin burrs are generated. Therefore, the resin thin burrs are removed by means of water jet or laser, in order to secure the satisfactory soldering plating property in the mounting process of semiconductor package. Or, it is carried out to cover the surface of terminals with a resin sheet so as to prevent the occurrence of resin thin burrs.

However, as to the former method, there is a problem that it is difficult to completely remove resin thin burrs and even if the removal of resin thin burrs is possible, it takes a long time to do the removal thereof. Further, as to the latter method, there is a problem that since the covering of the surface of terminals with a resin sheet is imperfect so that resin passes around behind terminals, it was impossible to rid terminals of burrs.

### SUMMARY OF THE INVENTION

An object of the present invention is to provide a process for making a semiconductor package in which the occurrence of resin thin burrs in the surface of terminal is prevented.

In order to attain the above-mentioned object, a process for making a semiconductor package, according to the present invention, comprises the steps of: mounting semiconductor devices on die-pads supported with suspending leads of lead frames, respectively; making wire-bonding of electrodes provided on the upper face of the semiconductor devices to terminals of the lead frames; then, individually molding the semiconductor devices with molding compound; thereafter stamping out the individual semiconductor devices, wherein resin tapes are stuck on the backsides of the terminals prior to the molding process, and the resin films are removed from the terminals after the molding process.

Further, in order to attain the same object, a process for making a semiconductor package, according to the present invention, comprises the steps of: mounting individual semiconductor device on die-pads supported with suspending leads of each of a plurality of lead frames which are arranged in matrix through grid leads provided with terminals in a frame; making wire-bonding of terminals provided on the upper faces of individual semiconductor devices to the terminals of the lead frames; then, individually molding these semiconductor devices with molding compound; thereafter, cutting the frame at the grid leads by means of dicing saw to form a plurality of semiconductor packages, wherein resin tapes are stuck on the backside of the terminals, and the resin tapes are removed from the terminals after the molding process.

In any of the above-mentioned methods, it is preferable that the sticking of resin tapes on the backside of the terminals is made by the laminating method.

Further, in any of the above-mentioned methods, it is preferable that either alkali-soluble resin tapes or water-soluble tapes may be used as the resin films.

### BREIF DESCRIPTION OF THE DRAWINGS

FIG. 1 is a sectional view of one example of semiconductor package.

FIG. 2 is a plan view of semiconductor package shown in FIG. 1.

FIG. 3 is an explanatory view of a frame of individually molding type.

FIG. 4 is an explanatory view of a frame of individually molding type.

FIG. 5 is a sectional view showing a state of apart of the process for making an individually molding type of semiconductor package.

FIG. 6 is a sectional view showing a state where resin tape is stuck on the lead frame shown in FIG. 5.

FIG. 7 is a sectional view showing a state of a part of the process for making a individually molding type of semiconductor package with another lead frame.

FIG. 8 is a sectional view showing a state where resin tape is stuck on the lead frame shown in FIG. 7.

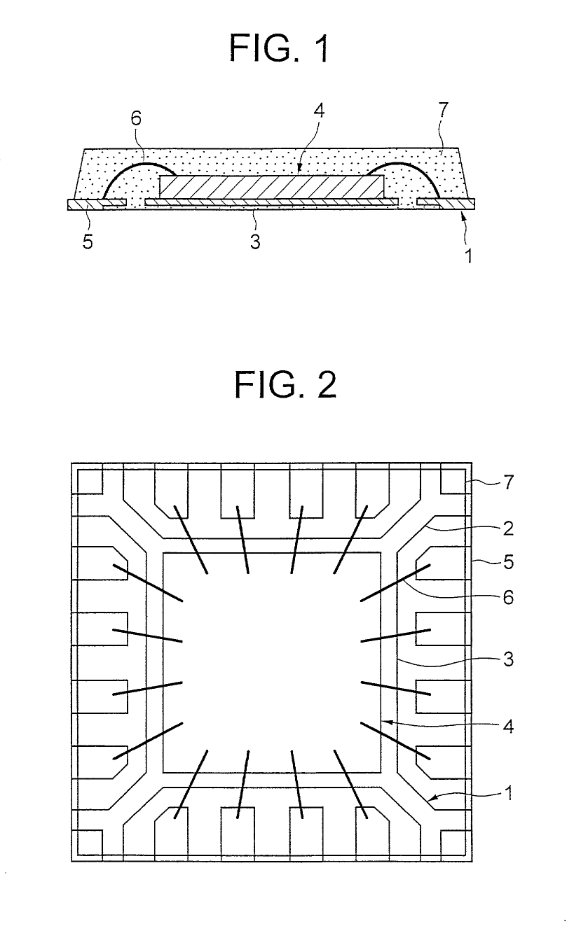

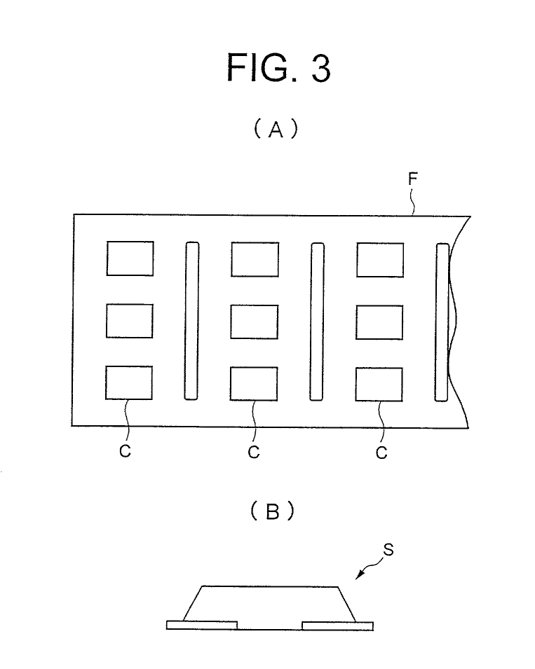

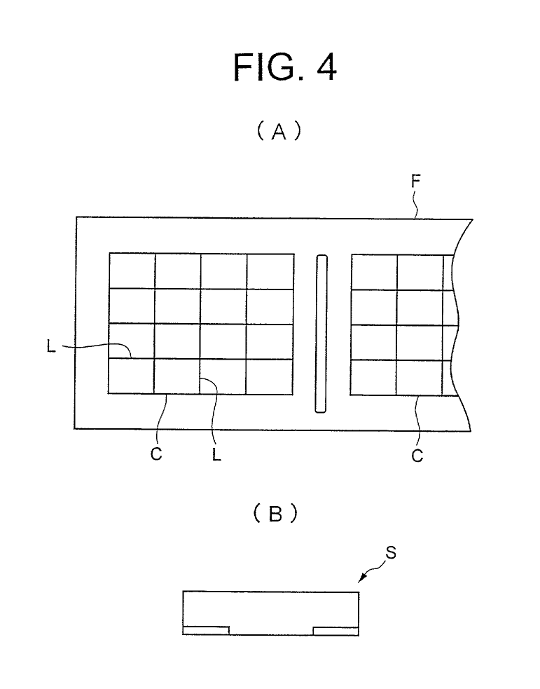

### PREFERRED EMBODIMENT OF THE INVENITON

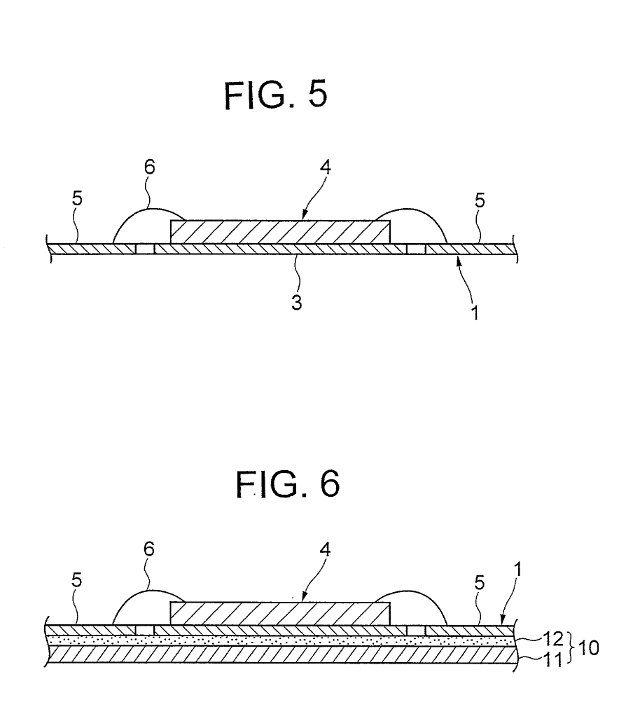

Then, referring to figures, embodiments of the present inventions are explained. FIG. 5 is a sectional view showing a state of a part of the process for making an individually molding type of semiconductor package, wherein semiconductor device 4 is mounted on die-pad 3 supported with suspending leads 2 of lead frame 1, and the wire-bonding of electrodes provided on the top face of semiconductor device 4 to terminals 5 of lead frame 1 is made through metal thin wire 6. Heretofore, the lead frame with semiconductor in the above-mentioned state was inserted into a mold and molding of semiconductor device with molding compound was made. In the present invention, resin tape 10 is stuck on the backside of terminals 5 prior to the molding process, as shown in FIG. 6, and semiconductor devices 4 are inserted into a mold and molded with molding compound, as the resin tapes 10 are stuck on the backside of terminals 5. Then molded semiconductor devices are stamped out to form individual semiconductor devices.

In this way, the lead frame with semiconductor device is molded with molding compound as the resin tape is stuck on the backside of terminals 5. Therefore, as resin is prevented from coming in behind the terminals 5, resin thin burrs on the backside of terminals 5 are not produced. Lead frame 1 shown in FIG. 5 is of a die-pad exposure type. In case of using the lead frame 1, the backside of die pad 3 is also covered with resin film 10 so that resin thin burrs are prevented from being produced.

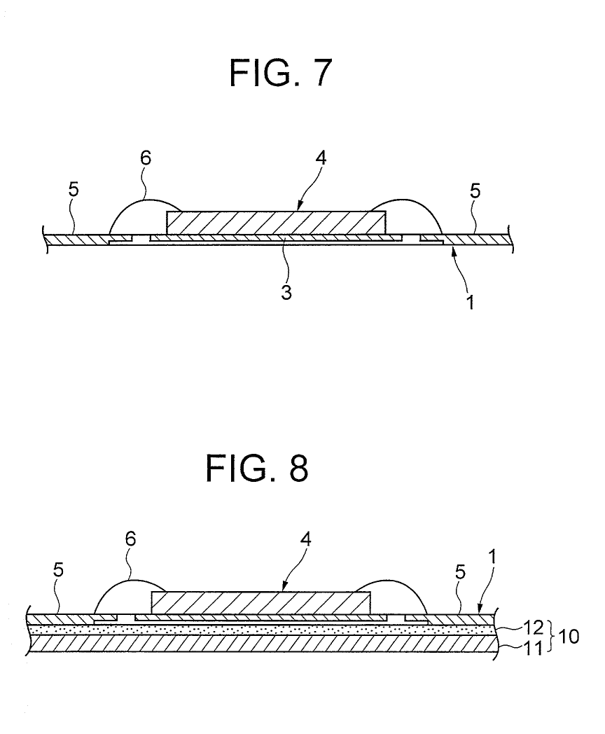

FIG. 7 is a sectional view showing a state of a part of the process for making an individually molding type of semiconductor package with another lead frame, wherein the lead frame 1 is half-cut by etching in such a manner that die-pad 3 is positioned above terminals 5 and inner ends of terminals 5 are half-cut by etching. Further, in the present invention, as shown in FIG. 8, resin tape 10 is stuck on the backside of terminals 5, and semiconductor devices are inserted into a mold to mold with molding compound4, as the resin tapes 10 are stuck on the backside of terminals 5. Then, semiconductor devices 4 are stamped out to form individual semiconductor packages.

In this way, semiconductor devices 4 are molded with molding compound, as resin tapes 10 are stuck on terminals 5. Therefore, since resin does not come in behind terminals 5, resin thin burrs are not generated on the backside of terminals 5. Lead frames 1 shown in FIG. 7 are of unexposed die-pad type. In a case where the lead frames 1 are used, resin for encapsulation also exists on the lower side of die-pads 3 and inner ends of terminals 5 so that the adhesion of resin for encapsulation with lead frames 1 are strengthened.

In the above-mentioned two examples, cases where individually molding type of semiconductor packages is made are explained. In a case where individually molding type of semiconductor packages is made, molding is carried out in the same way as the above-mentioned method.

Namely, the production of individually molding type of semiconductor packages differs from individually molding type of semiconductor packages in that a frame provided with a plurality of lead frames arranged in matrix through grid leads provided with terminals are used. Semiconductor devices are mounted on die-pads supported with suspending leads of respective lead frames, respectively, and wire -bonding of electrodes provided on the top faces of semiconductor devices and terminals of lead frames are made through thin metal wires. Then, resin tapes are stuck on the backside of terminals. The semiconductor devices with lead frames are inserted into a mold to be individually molded as the resin tapes are stuck on the backside of terminals. Then, individually molded semiconductor devices are cut at grid leads by means of dicing saw to form a plurality of semiconductor packages.

In the case where individually molding type of semiconductor is made, resin is prevented from coming behind terminals by molding individually semiconductor devices with molding compound. Accordingly, thin burrs are not generated on the backside of terminals.

In the present invention, adhesive 12 applied on base film 11 can be used as resin tape 10. The base film 11 is a heat-resisting tape withstanding the heat history in the process for assembling semiconductor packages, wherein resin in which outgasssing is little or nothing can be used optionally.

Polyimide is preferably used as base film 11 of resin tape 10. Resin tape having base film of polyimide withstands fully the heat history in the process for assembling semiconductor packages, wherein the occurrence of gas having a bad influence on the property of wire bonding is controlled at the minimum. As a concrete example of resin tape having base film of polyimide, there is given “TRM6250” manufactured by Nitto Denko Co., Ltd.

Further, alkali-soluble film or water-soluble film can be used as resin tape 10. When using alkali-soluble film, the resin tapes can be easily removed by pre-treating for soldering plating in the mounting process of semiconductor package. Further, when using water-soluble film as resin film 10, the resin film can be easily removed using hot water.

As above-mentioned, a process for making a semiconductor package of the present invention, in either individually molding type of semiconductor package or individually molding type of semiconductor package, resin tapes are stuck on the backside of terminals prior to the molding process, and the resin tape is removed from the terminals after the molding process, by which resin is prevented from coming in behind terminals. Accordingly, thin burrs are not generated on the backside of terminals. The satisfactory property of soldering plating in the mounting process of semiconductor process can be secured even without the process for removing burrs, which are conventionally done.

What is claimed is:

1. A process for making a semiconductor package comprising the steps of: mounting semiconductor devices on die-pads supported with suspending leads of lead frames, respectively; making wire-bonding of electrodes provided on the upper face of the semiconductor devices to terminals of the lead frames; then, individually molding the semiconductor devices with molding compound; thereafter stamping out the individual semiconductor devices, wherein resin tapes are stuck on the backsides of the terminals prior to the molding process, and the resin films are removed from the terminals after the molding process.

2. A process for making a semiconductor package, comprising the steps of: mounting individual semiconductor device on die-pads supported with suspending leads of each of a plurality of lead frames which are arranged in matrix through grid leads provided with terminals in a frame; making wire-bonding of terminals provided on the upper faces of individual semiconductor devices to the terminals of the lead frames; then, individually molding these semiconductor devices with molding compound; thereafter, cutting the frame at the grid leads by means of dicing saw to form a plurality of semiconductor packages, wherein resin tapes are stuck on the backside of the terminals, and the resin tapes are removed from the terminals after the molding process.

3. A process for making a semiconductor package as claimed in claim 1 or 2, wherein the sticking of resin tapes on the backside of terminals is made by the laminating method.

4. A process for making a semiconductor package as claimed in any of claims 1 through 3, wherein polyimide films with adhesive layers are used as the resin tapes.

5. A process for making a semiconductor package as claimed in claims 1 through 3, wherein alkali-soluble resin tapes are used as the resin films.

6. A process for making a semiconductor package as claimed in claim 1 through 3, wherein water-soluble resin tapes are used as the resin film.
